(19) United States
(12) Patent Application Publication
(10) Pub. No.: US 2006/0057814 A1
(43) Pub. Date: Mar. 16, 2006

(54) Fabricating a memory cell arrangement

(76) Inventor: Rolf Weis, Dresden (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/220,918

(22) Filed: Sep. 8, 2005

(30) Foreign Application Priority Data
Sep. 10, 2004 (DE) 10 2004 043 858.7

(51) Int. Cl. H01L 21/20

(52) U.S. Cl. 438/386

(57) ABSTRACT

A method is described for fabricating a DRAM memory cell, which includes a trench capacitor and a select transistor. After the capacitor trench has been etched and optionally the first capacitor electrode has been produced, the trench is filled with a dummy filling. After the gate electrode and the first and second source/drain regions have been provided, the dummy filling is removed, and the capacitor dielectric and the second capacitor electrode are provided. As a result, it is possible to use temperature-sensitive materials for the capacitor dielectric and the second capacitor electrode despite the use of high-temperature steps. In the memory cell arrangement formed by this method, the direction of the conductive channel, which connects first and second source/drain regions to one another, can differ from the direction of the bit lines and of the word lines (e.g., by 45°).

### CROSS REFERENCE TO RELATED APPLICATIONS

This application claims priority under 35 USC §119 to German Application No. 10 2004 043 858.7, filed on Sep. 10, 2004, and titled “Method for Fabricating a Memory Cell, Method for Fabricating a Memory Cell Arrangement, and Memory Cell Arrangement,” the entire contents of which are hereby incorporated by reference.

### FIELD OF THE INVENTION

The present invention relates to a method for fabricating a memory cell, to a method for fabricating a memory cell arrangement, and to a memory cell arrangement.

### BACKGROUND

Memory cells of dynamic random access memories (DRAMs) generally comprise a storage capacitor and a selection transistor. An information item is stored in the storage capacitor in the form of an electrical charge, which represents a logic quantity 0 or 1. By driving the read-out or selection transistor via a word line, the information stored in the storage capacitor can be read out via a bit line. For reliable storage of the charge and distinguishability of the information read out, the storage capacitor must have a minimum capacitance. The lower limit for the capacitance of the storage capacitor is presently about 25 fF.

The response of the select transistor causes the storage capacitor to be written to or read. Since the capacitor charge of the storage capacitor drops very quickly on account of recombination and leakage currents, the charge is generally refreshed at millisecond intervals.

Since the storage density increases from memory generation to memory generation, the required area of the one-transistor memory cell has to be reduced from generation to generation. At the same time, the minimum capacitance of the storage capacitor has to be maintained, so that a sufficiently high read signal from the DRAM memory cell is maintained.

Up to the 1 Mbit generation, both the read-out transistor and the storage capacitor were realized as planar components. Starting with the 4 Mbit memory generation, a further reduction in the area of the memory cell was obtained through a three-dimensional arrangement of the storage capacitor. One possibility consists in realizing the storage capacitor in a trench. In this case, by way of example, a diffusion region adjoining the wall of the trench and also a doped polysilicon filling in the trench act as electrodes of the storage capacitor. The electrodes of the storage capacitor are thus arranged along the surface of the trench. This enlarges the effective area of the storage capacitor, on which the capacitance depends, relative to the space requirement for the storage capacitor at the surface of the substrate, which corresponds to the cross section of the trench. The packing density can be increased further by reducing the cross section of the trench while simultaneously increasing its depth.

A further configuration of a three-dimensional storage capacitor is what is known as the stacked capacitor, which is likewise laterally adjacent to the select transistor and is preferably arranged substantially above the select transistor, with the inner capacitor electrode being conductively connected to the select transistor.

Numerous measures have been implemented in the past in order to increase the storage capacitance of the trench capacitors. One measure is scaling the thickness of the storage dielectric. Furthermore, it is possible to enlarge the surface within the trench capacitor by wet-chemical expansion of the trench structure (bottle). Moreover, it is possible to enlarge the surface within the trench by a roughness, for example by HSG polysilicon coating.

Further approaches comprise minimizing the electrode depletion of the capacitor electrodes by increasing the doping of the Si electrode material, or the use of metal electrodes, as a result of which the resistance of the electrodes can at the same time be drastically reduced. In addition, the previous NO dielectric may be replaced by a high-k dielectric in order to increase the capacitance of the trench capacitor.

High-k dielectrics usually lose their advantageous properties when they are heated to relatively high temperatures, i.e. temperatures of greater than 600 to 700° C.

The use of high-k dielectrics would permit the surface area required for the storage capacitor with a predetermined storage capacitance to be reduced, thereby allowing the size of a predetermined cell to be reduced without a loss of capacitance. As a result, the retention time, i.e. the time for which a stored charge is stored in a form such that it can be recognized again, can be maintained while reducing the space taken up.

The integration of high-k dielectrics into current DRAM technology with trench capacitors has been subject to limits, since after the trench capacitor has been formed, and in particular after the storage dielectric and the upper capacitor electrode have been deposited, a number of high-temperature steps, in particular heat treatment steps, which are required to complete the components, are carried out. By way of example, high-temperature steps are required for the oxidation of the isolation trenches, which laterally delimit the active areas, for steps of oxidizing the side walls of the gate electrodes and for producing oxide sacrificial layers.

The current DRAM process for fabricating a DRAM memory cell with trench capacitor takes the following order:
forming the capacitor trench,
forming the capacitor with lower capacitor electrode, storage dielectric, upper capacitor electrode,
forming the isolation trenches,
forming the gate electrodes,
producing the MOL metallization level,
producing the BEOL metallization level.

In this process, the steps of forming the isolation trenches, the gate electrodes and of providing the source/drain regions comprise high-temperature steps. By way of example, heat treatment steps are carried out at approximately 950° to 1000° C. to activate the highly doped source/drain regions.

In DRAM memory cells which are currently in use, the electrical connection between second capacitor electrode and first source/drain region of the select transistor is realized by a buried, highly doped terminal region (buried strap). However, a buried strap of this type has the problem of outdiffusion from the highly doped region and the buried strap terminal can only be contact-connected on one side, and finally a minimum distance is always required between the highly doped regions to ensure that the properties of the apparatus are not impaired.

### SUMMARY

An object of the present invention is to provide an improved method for fabricating a memory cell arrangement.

This and other objects are achieved in accordance with the present invention by providing a method for fabricating a memory cell, which is at least partially arranged in a semiconductor substrate and includes a storage capacitor, which is designed as a trench capacitor and is suitable for storing electrical charge, and a select transistor, which is suitable for driving the storage capacitor. The method comprises providing a semiconductor substrate, and etching a trench into a surface of the semiconductor substrate, producing a trench wall. The method also comprises providing the select transistor with a first and a second source/drain region, a conductive channel in the semiconductor substrate, which extends between the first and second source/drain regions, and a gate electrode, and forming the storage capacitor with a first capacitor electrode, which is adjacent to the trench wall, a dielectric layer, which is adjacent to the first capacitor electrode, and a second capacitor electrode, which is adjacent to the dielectric layer. The method further comprises electrically connecting the second capacitor electrode to the first source/drain region of the select transistor. The forming of the dielectric layer and the second capacitor electrode are carried out after the step of providing the first and second source/drain regions.

According to the present invention, the dielectric layer and the second capacitor electrode are formed after providing the source/drain regions and the gate electrode. In this context, the term “providing” encompasses not only doping but also in particular carrying out the required high-temperature treatment steps at temperatures of higher than 900°, 800° or even 700° C., so as to electrically activate the doped regions. This makes it possible to carry out all the method steps which require a high temperature before the dielectric layer is formed. Accordingly, the dielectric layer can be formed from a temperature-sensitive material, in particular from a material with a high dielectric constant, without this property being lost as a result of a subsequent high-temperature step. Furthermore, it is also possible for a temperature-sensitive material, in particular a highly conductive material, to be used as material of the second capacitor electrode. Consequently, the capacitance of the capacitor, and therefore the performance of the resulting memory cell, can be greatly increased.

Since the components made from temperature-sensitive materials are formed after the forming the source/drain regions and the gate electrode, process steps that require a high temperature can also be used to form the gate electrode in accordance with the invention, which differs from conventional processes where such high temperature process steps have not been used or have been modified so as to reduce the thermal load on the already deposited dielectric layer and second capacitor electrode that have already been deposited.

The transistor of the memory cell of the invention can be of any desired design and may in particular comprise what is known as a fin-FET.

According to the present invention, the capacitor trench is filled with dummy material which is removed again after the steps of forming the source/drain regions and the gate electrode. Suitable dummy materials are materials that are thermally stable during the high-temperature steps that are to be carried out and that can be completely removed again after the high-temperature steps have been carried out. Examples of dummy materials include in particular silicon and silicon-germanium alloys, which are advantageous since they have a higher etching selectivity.

The step of forming the first capacitor electrode can include the step of doping the substrate region that is adjacent to the trench wall and/or depositing a metal layer. In other words, the first capacitor electrode may, for example, be composed of a highly doped trench wall region and an adjacent metal layer. Preferably, the step of doping the substrate region that is adjacent to the trench wall can be carried out at an earlier stage in the method, since this step is usually carried out at very high temperatures. By way of example, the doping source material used may be a highly doped material, such as arsenic glass, out of which the dopants diffuse during a heat treatment step.

The step of forming the first capacitor electrode can be carried out before or after the step of forming the gate electrode. More specifically, it is possible first of all to form the capacitor electrode, to fill the remainder of the capacitor trench with a dummy filling, which will subsequently be removed, and then to carry out the further method steps for fabricating the memory cell. Alternatively, however, it is also possible, for example after the step of doping the substrate region which adjoins the trench wall, to fill the capacitor trench with the dummy material and only to be filled with the first capacitor electrode, the storage dielectric and the second capacitor electrode after completion of the further components of the memory cell and in particular of the gate electrode.

If the step of forming the first capacitor electrode comprises the steps of doping the substrate region which is adjacent to the trench wall and of depositing an electrode material, in particular the doping step can be carried out first of all; then, the gate electrode is formed, and after that the electrode material is deposited.

Expressed in a more general way, in a multi-stage method for fabricating the first capacitor electrode, some of the steps are carried out before the gate electrode has been provided, and some of the steps are carried out after the gate electrode has been provided.

According to the present invention, it is particularly preferred for the step of electrically connecting second capacitor electrode to the first source/drain region of the select transistor to be carried out after the step of forming the second capacitor electrode. It is particularly preferred for this electrical connection to be realized by a surface terminal, i.e. what is known as a surface strap or plug strap. This makes it possible to avoid the drawbacks associated with the buried strap, i.e. in particular outdiffusion and the problem of connection on one side.

The method according to the invention in particular produces a memory cell including a planar select transistor, i.e. a select transistor in which the current flow is substantially horizontal with respect to the substrate surface. More accurately, the effective distance covered by the cell current in the horizontal direction is greater than the effective distance covered in the vertical direction. In this context, the term “effective” distance is to be understood as meaning the sum of the individual distances covered. For example, if the current flows a distance x downward, a distance z in the horizontal direction and a distance y upwards, the effective distance covered in the vertical direction is |x−y|, and according to the present invention it is preferably the case that |z|>|x−y|.

In the method according to the invention for fabricating a memory cell arrangement, the gate electrodes for each memory cell are first of all produced insulated from all the other gate electrodes which are assigned to a particular word line and are only connected via a word line to the other gate electrodes assigned to the corresponding word line in a subsequent step. This prevents all the capacitor trenches from being covered by passive word lines, and correspondingly no longer being accessible, after the gate electrode has been formed. Since the capacitor trenches are still freely accessible after the gate electrodes have been formed, it is possible for the dummy material which has been introduced into the capacitor trenches to be removed and for the dielectric layer and the second capacitor electrode to be formed.

Preferably, the step of defining the conductive channel is carried out in such a manner that the direction of the conductive channel differs from the direction of the bit line and of the word line. The step of defining the conductive channel comprises the step of forming active areas, which can, for example, be isolated from one another by isolation trenches. The conductive channel belonging to a select transistor is formed between the first and second source/drain regions. Since the direction of the conductive channel differs from the direction of the bit lines, the word lines can be arranged in such a way that they run precisely between the capacitor trenches. Accordingly, there are no longer any passive word lines running above the capacitor trenches, which means that even after the gate electrodes have been formed the capacitor trenches are accessible, so that their dummy filling can be removed and they can be filled with a capacitor dielectric and a second capacitor electrode.

According to the present invention, it is particularly preferred for the direction of the conductive channel to differ by 45° from the direction of the bit line. In this case, the memory cell arrangement can be configured in such a manner that the capacitor trenches are in each case arranged in the form of a regular grid, with the active areas in each case forming the diagonal. Accordingly, the word lines can be formed between two adjacent columns or rows of capacitor trenches. If the capacitor trench arrangement is rotated through 45° with respect to a checkerboard-like arrangement, the further advantage is achieved that the trenches are arranged in accordance with the preferred crystallographic direction, making it easier to carry out an analysis using the scanning electron microscope.

In the event of a rotation through 45°, the distance between the word lines and the bit lines is in each case \sqrt{8}/F.

With this embodiment, it is also possible for the gate electrode of each memory cell initially to be produced insulated from all the other gate electrodes which are assigned to a specific word line and only to be connected via the word line to the other gate electrodes assigned to the corresponding word line in a subsequent step. This means that even with an arrangement of the memory cells as defined above, it is possible for the formation of gate electrodes and word lines to be carried out in separate steps.

Furthermore, a memory cell arrangement can be provided such that the capacitor trenches are arranged in the form of a regular grid, so that a memory cell is assigned to each intersection between a bit line and a word line. Since the active areas are oriented obliquely with respect to the direction defined by the bit lines or the word lines, it is possible to increase the effective channel length of the conductive channel between first and second source/drain regions for the same minimum feature size.

This improves the characteristic variables I_{ON} and I_{OFF}. Furthermore, it is preferable for the direction of the conductive channel to differ by 45° from the direction of the bit line.

Moreover, in this embodiment, in a cross section along the conductive channel region, the lower edge of the gate electrodes is in each case arranged at a different height from the lower edge of the word line, this height being measured perpendicular to the substrate surface. More specifically, in this embodiment, the gate electrodes have in each case been formed independently from the word lines. Consequently, the gate electrode is formed in sections, so that it is present above the active areas. The gate electrode sections assigned to a word line are connected to one another via the word line.

The above and still further objects, features and advantages of the present invention will become apparent upon consideration of the following detailed description of specific embodiments thereof, particularly when taken in conjunction with the accompanying drawings where like numerals designate like components.

### BRIEF DESCRIPTION OF THE DRAWINGS

FIGS. 1A, 1C, 2A, 3A, 4A, 5-14A, 15, 16A, 17A and 18A show cross-sectional views of a memory cell array after individual process steps have been carried out in accordance with a first exemplary embodiment of the present invention.

FIGS. 1B, 2B, 3B, 4B, 14B, 16B and 18B show plan views of the memory cell array after individual process steps have been carried out in accordance with the first exemplary embodiment of the present invention.

FIGS. 19-26 show plan views od memory cell arrays after corresponding process steps have been carried out in accordance with a second exemplary embodiment of the present invention.

FIG. 27 shows a block circuit diagram of a memory cell arrangement which results in accordance with the second exemplary embodiment; and

FIG. 28 shows an exemplary embodiment of bit lines and memory cells for increasing read accuracy in accordance with the invention.

### DETAILED DESCRIPTION

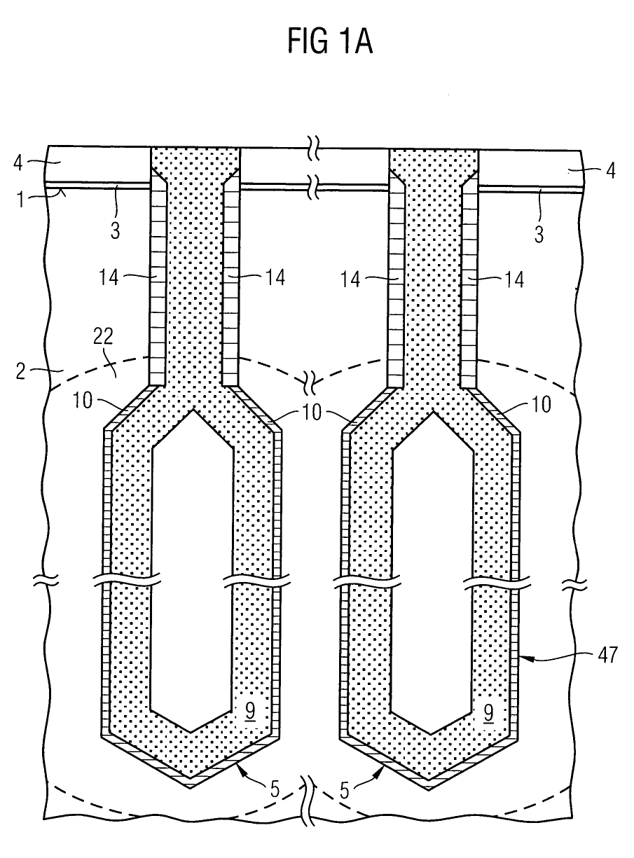

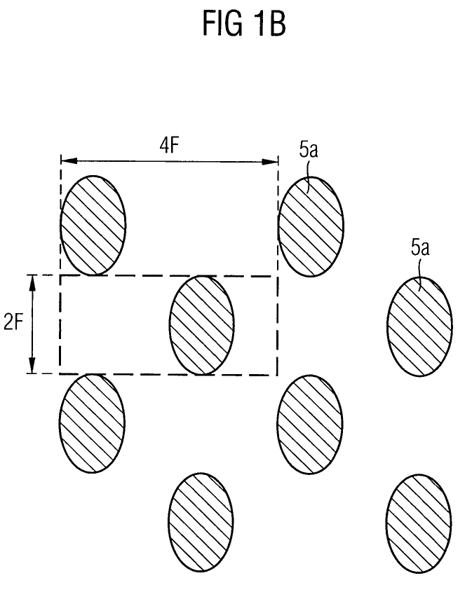

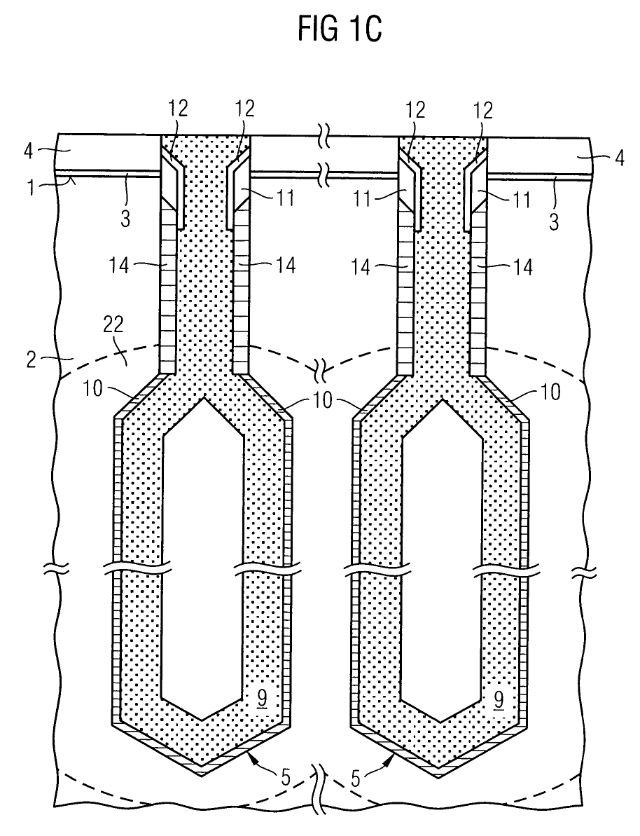

FIGS. 1 to 18 illustrate a first exemplary embodiment of the present invention, where after the gate electrode has been formed the metal layer of the first capacitor electrode, the capacitor dielectric and the second capacitor electrode are provided, and the production of the word lines is separated from the production of the gate electrodes. In other words, the gate electrodes for the respective select transistors are provided independently of the word lines that are to be produced subsequently. For this reason, after the gate electrode has been formed, there are no passive word lines running above the capacitor trench and blocking access to the capacitor trench. The word lines are therefore only produced after completion of the trench capacitor, i.e., after the capacitor trench has been filled with the capacitor dielectric and the upper capacitor electrode, and the production of the word lines preferably does not include any high-temperature steps.

The starting point for the first exemplary embodiment of the present invention is the structure shown in FIG. 1A. To produce the structure shown in FIG. 1A, an approximately 3 mm thick SiO₂ (oxide) layer 3 and an approximately 200 nm thick Si₃N₄ layer 4 are applied to a surface 1 of a semiconductor substrate 2. A 1 μm thick BPSG layer (not shown) is applied above this.

Using a photolithographically produced mask (not shown), the BPSG layer, the Si₃N₄ layer 4 and the SiO₂ layer 3 are patterned in a plasma etching process using CF₄/CHF₃, so as to form a hard mask. Using this hard mask as an etching mask, trenches 5 are etched into the main surface 1 in a further plasma etching process using HBr/NF₃, with a trench wall 47 being uncovered within each trench 5.

It is preferable for the trench to be etched in such a manner that the trench is widened in its lower region and has a larger diameter there than in an upper region. This can be done by a conventional wet bottle method.

Subsequently, the BPSG layer is removed by a wet etch using H₂SO₄/HF.

The trenches 5, by way of example, have a diameter of 100 nm in their upper region and a diameter of 120 to 130 nm in their lower region. The depth of the trenches 5 is approximately 6 to 7 μm, and the distance between them is approximately 100 nm. The distance from the substrate surface to the widened region is approximately 1 μm.

Conventional methods are used to form the first capacitor electrode 6, in particular by a buried plate doping step, by which all the lower capacitor electrodes are connected to one another via a common n⁺-doped region 22, by a known method, in particular by filling the trench with a highly doped silicate glass layer and carrying out a heat treatment step for outdiffusion or gas phase doping. Furthermore, a Si₃N₄ layer 10 with a thickness of from 5 to 10 nm is formed, the lower trench part is filled with intrinsic polysilicon, and the insulation collar 14 is formed in the upper trench part using known methods. The insulation collar 14, which is usually produced from SiO₂, has the purpose of suppressing a parasitic transistor which would otherwise form at this location.

The resulting structure is filled with intrinsic polysilicon. The Si₃N₄ layer 10 and the polysilicon filling 9 form a dummy filling for the trench capacitor, which are removed again after the high-temperature steps have ended. The dummy filling used must be completely thermally stable and must also be completely removable even after high-temperature steps. In all the embodiments of the present invention, the Si₃N₄ layer 10 is particularly preferred in order to ensure that the dummy filling can subsequently be removed. It is also possible for silicon-germanium to be used as an alternative material instead of the intrinsic polysilicon. When the dummy material is being applied, a cavity is formed in the interior of the capacitor trench. The result is the structure shown in FIG. 1A.

FIG. 1B shows a plan view of the arrangement of the defined capacitor trench regions 5a. The defined trench regions 5a are arranged in a checkerboard pattern, i.e. they are arranged in rows and columns, with the defined trench regions of adjacent rows or columns in each case being arranged offset with respect to one another. The maximum diameter of a defined trench region at the surface 2 is F, and the distance between two defined trench regions 5a is 4 F, where F denotes the minimum feature size of the particular technology.

Alternatively, the trench structure shown in FIG. 1C, in which source/drain regions have in each case been formed in an upper trench region above the insulation collar 14 by selective epitaxial growth of single-crystal silicon material 11, can also be used as a starting point for implementing the present invention. In a subsequent step, these source/drain regions are insulated from the polysilicon material 9 that is subsequently to be introduced by an Si₃N₄ layer 12. The arrangement shown in FIG. 1C makes it possible to provide source/drain regions that are spatially elevated with respect to the substrate surface 1. As a result, the distance between source/drain region and gate electrode can be increased further, which is advantageous since this arrangement increases the channel length. Furthermore, the total length of the active area is increased by the epitaxially grown regions.

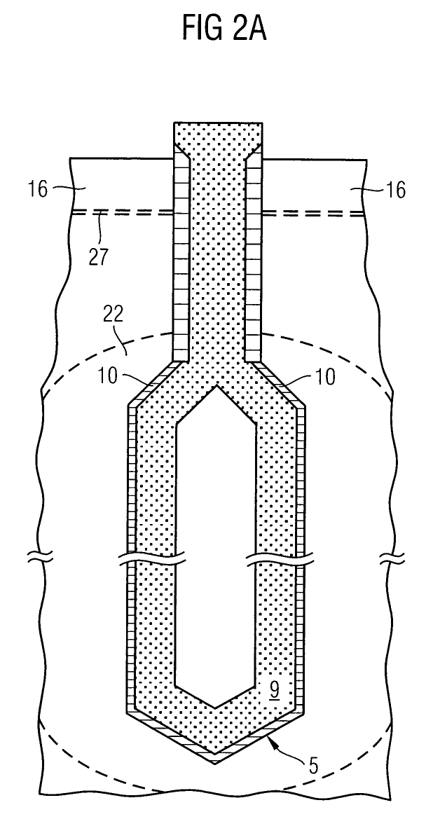

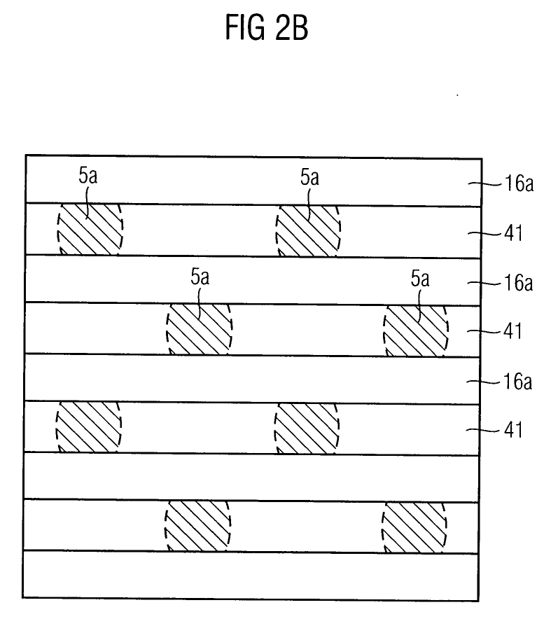

In a subsequent step, the active areas are defined by defining isolation trenches 16a which are filled with an insulating material, for example an Si₃N₄ liner layer 27 and an SiO₂ layer 16. The arrangement of defined insulation regions 16a and defined active areas 41 is illustrated in FIG. 2B. FIG. 2A illustrates a cross-sectional view through the capacitor trench shown in FIG. 1A, with insulation structures which are produced in front of or behind the plane of the drawing illustrated indicated by dashed lines. FIG. 2A illustrates in particular the etching depth down to which the insulation structures 16 are produced.

It should be noted that, by etching the isolation trenches, the regions of the trench capacitors 5a which extend into the insulation regions 16a, are of course removed.

In a subsequent step, the gate electrodes 17 are defined. For this purpose, first of all the Si₃N₄ layer 4 and the SiO₂ layer 3 are removed. Then, the gate oxide layer 48 and the gate electrodes made from polysilicon 17 with an Si₃N₄ capping layer 29 are locally produced at the locations at which the gate electrode of the select transistor will subsequently be present. This can be done, for example, by depositing a polysilicon layer and an Si₃N₄ capping layer over the entire surface and then patterning these layers, or by what is known as a Damascene process, in which an auxiliary layer is deposited and then patterned, with the surface regions at which the gate electrode is to be formed being uncovered. By subsequent deposition of a polysilicon layer and planarization of the resulting surface, polysilicon is deposited only at the locations at which the gate electrode is also to be formed. The auxiliary layer is then removed.

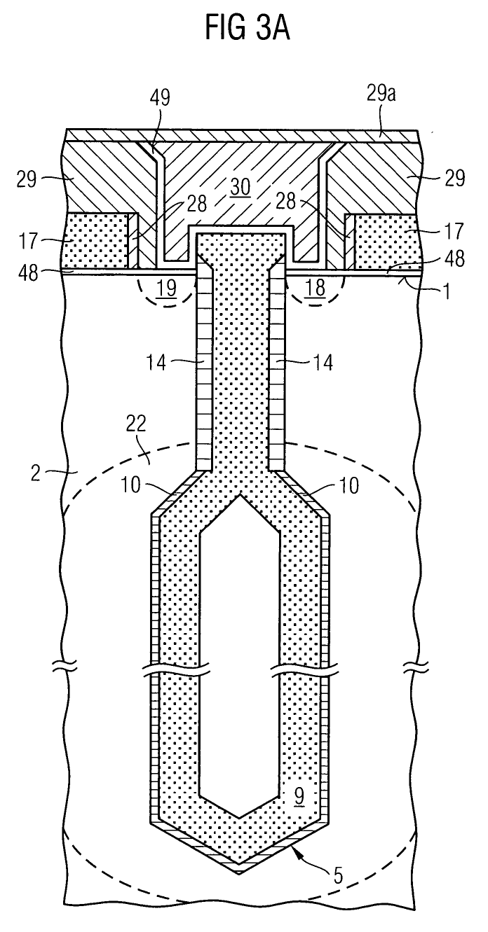

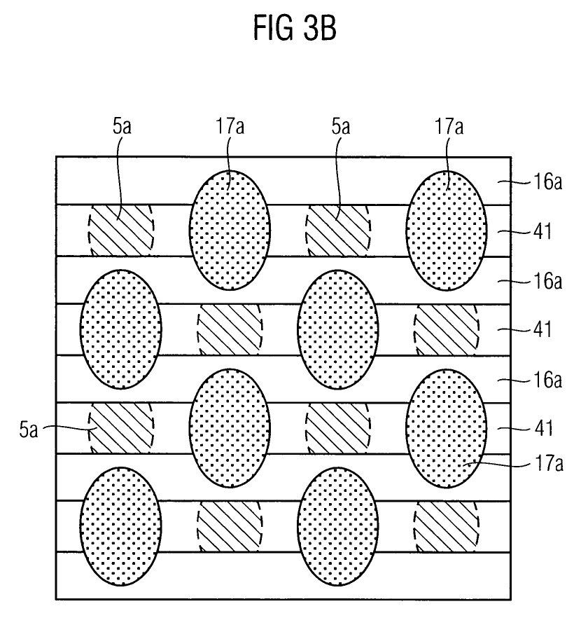

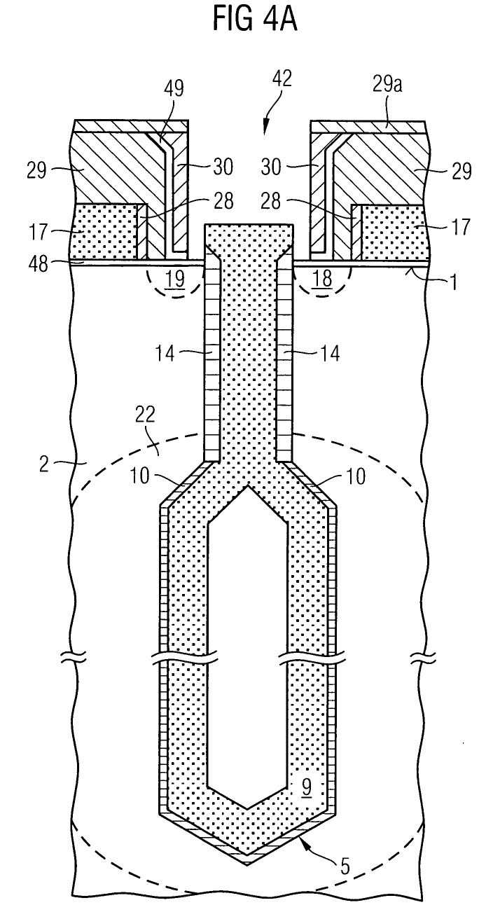

After the polysilicon material for the gate electrode has been deposited, the first and second source/drain regions 18, 19 are produced by known methods, in particular by ion implantation. This is followed by the standard further steps used for the fabrication of a gate electrode. In particular, an oxidation step is carried out to produce a side wall oxide layer 28, and an Si₃N₄ spacer is produced. Thereafter, the uncovered regions between the gate electrodes 17 are filled with an Si₃N₄ lining layer 49 and a BPSG layer 30, a planarization step down to the top edge of the Si₃N₄ capping layer 29 is carried out, and then front and back surfaces of the wafer are covered with Si₃N₄ layer 29a. The resultant structure is shown in FIG. 3A.

FIG. 3B shows a plan view of the resulting arrangement of capacitor trenches. A defined gate electrode region 17a is in each case provided between adjacent defined trench regions 5a. Unlike in the case of conventionally formed word lines, which would in each case run in strip form, perpendicularly with respect to the active areas 41, above the defined trench regions 5a, these defined gate electrode regions 17a are only formed locally. This means in particular that even after the gate electrodes 17 have been formed, the capacitor trenches are accessible from above or are covered by capping layers that can subsequently be removed again and are not required for the functioning of the memory cell.

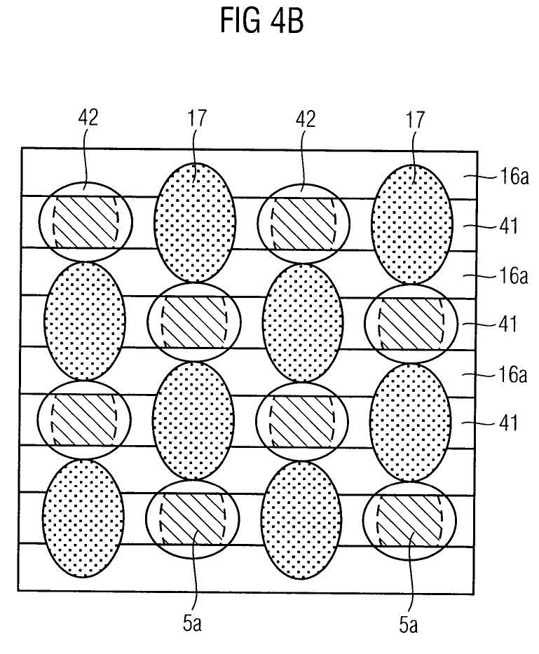

In a subsequent step, the surfaces of the capacitor trenches 5 are uncovered using a further etching mask, the DT mask II. The openings within the substrate surface are firstly photolithographically patterned and opened up by etching the Si₃N₄ layer 29a and the BPSG layer 30 below it. The result is the structure shown in FIG. 4A.

FIG. 4B shows a plan view of the resulting capacitor trench arrangement. The openings of the DT mask II 42 are in each case arranged above the defined trench regions Sa, so that after the corresponding holes have been etched in the BPSG layer 30, the capacitor trenches 5 are accessible again.

To protect the surface region which now remains between capacitor trench 5 and the residues of the BPSG layer 30, in a subsequent step an Si₃N₄ filling 31 is introduced into this space. This is usually done by applying the Si₃N₄ layer in a thickness which is greater than twice the width of this region, with the result that the previously free space is filled, and then etching back this layer.

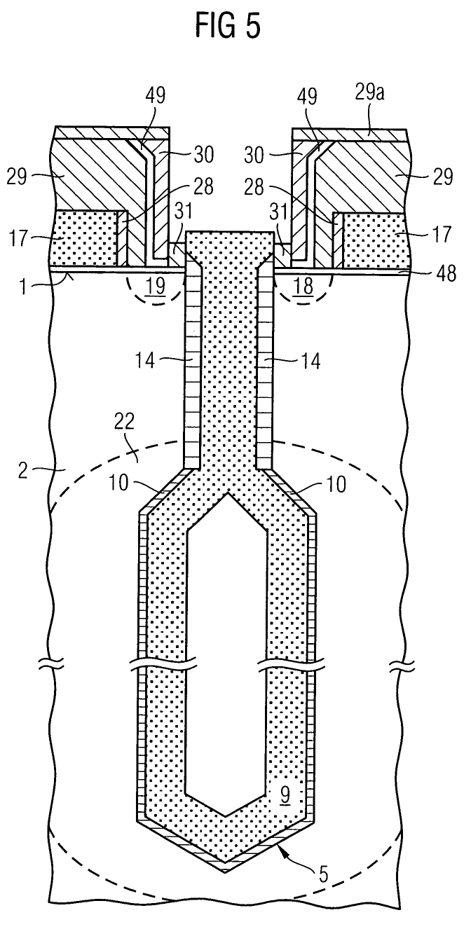

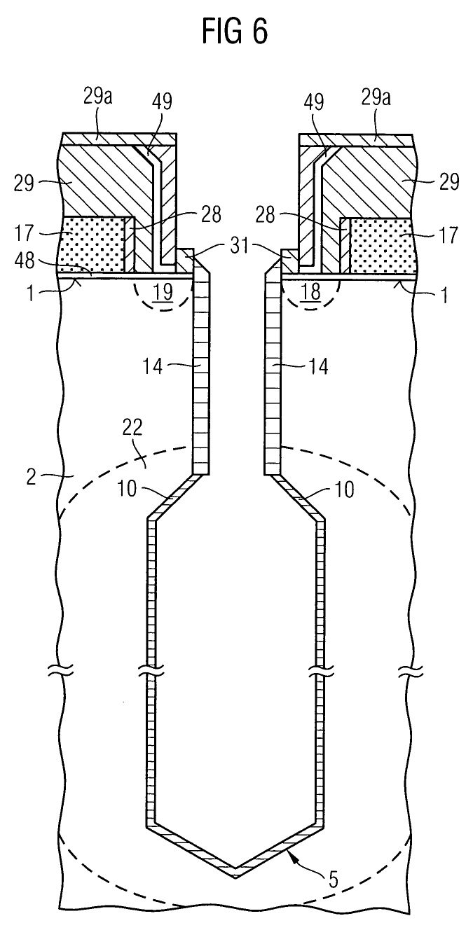

As a result, the active area which lies below the region 31 is protected from the subsequent step of etching the polysilicon 9 that has been introduced into the capacitor trench. The result is the structure shown in FIG. 5. Then, the polysilicon filling 9 is removed from the capacitor trench 5 by wet-chemical etching using NH₄OH. The result is the structure shown in FIG. 6.

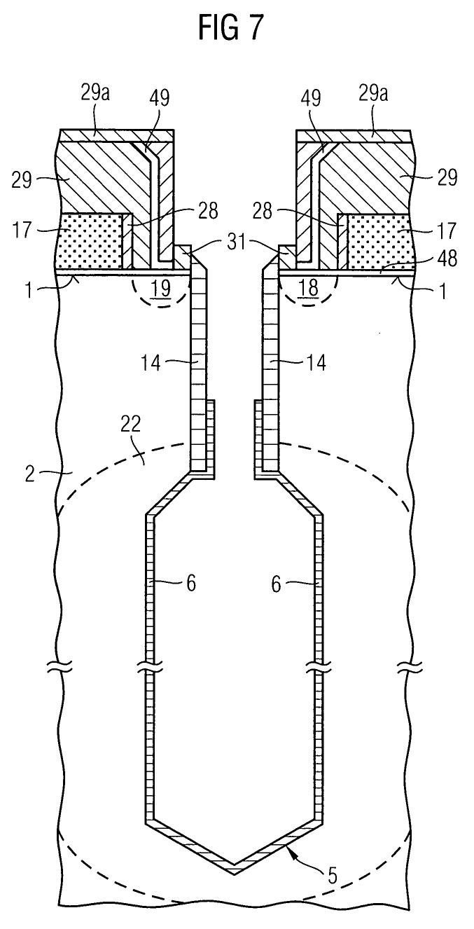

As shown in FIG. 7, the first capacitor electrode 6 is then formed. First, the Si₃N₄ layer 10 is removed from the lower trench region. Next, the material of the first capacitor electrode is applied in such a manner that it extends as far as above the lower edge of the collar region 14. This can be done, for example, by applying a metal layer over the entire surface, filling the capacitor trench with a TEOS-SiO₂ layer, applying a resist material, patterning the resist material, so that that part of the resist layer which is present in the upper trench region is uncovered, wet-etching the uncovered SiO₂ layer, etching the uncovered metal layer and removing the remaining SiO₂ material.

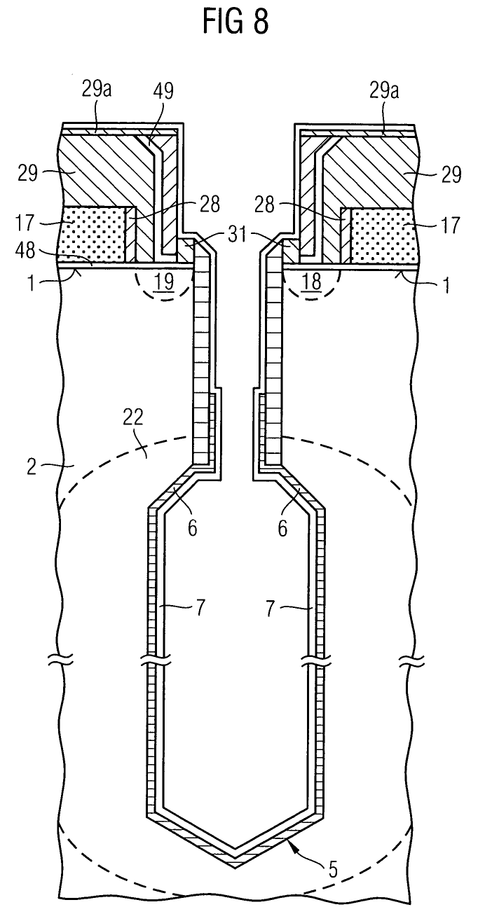

Then, a dielectric layer 7 is applied over the entire surface. The material of the dielectric layer is preferably a high-k dielectric such as, for example, Al₂O₃ or HfO₂. The result is the structure shown in FIG. 8.

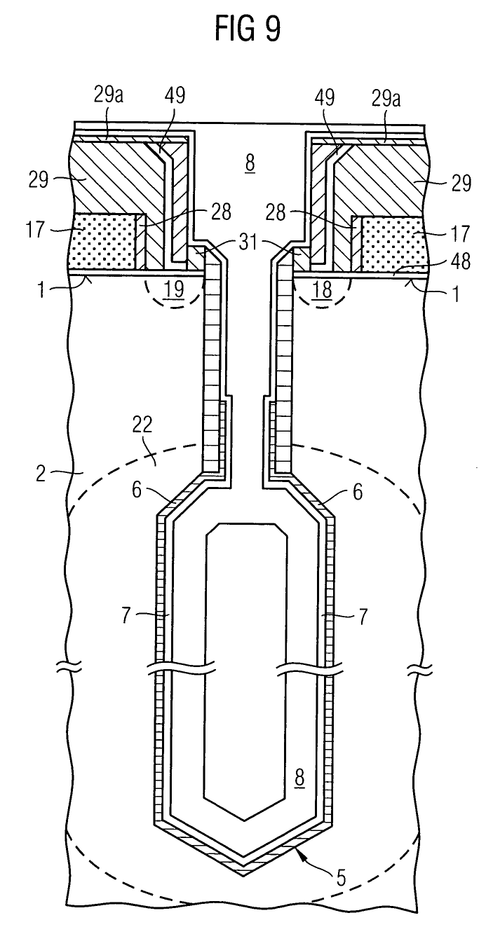

Then, as shown in FIG. 9, the material of the second metal electrode 8 is applied. The material of the first metal electrode 6 may be any desired metal or a metal compound and may in particular comprise refractory metals, refractory metal compounds, in particular tungsten, tungsten silicide or other metal silicides, Ti, TiN, Wo, Ru or Al, or alternatively polysilicon. The material of the second metal electrode 8 may comprise the same materials and may be identical to or different from the material of the first metal electrode. The result is the structure shown in FIG. 9. As can be seen in FIG. 9, a cavity is formed in the interior of the capacitor trench.

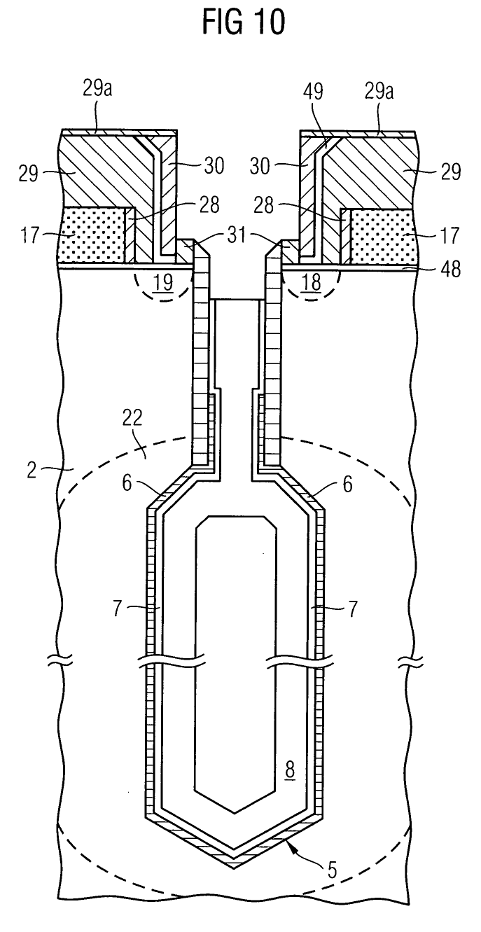

In a subsequent step, the second metal electrode layer 8 is etched back and the dielectric layer 7 which is uncovered is removed. On account of the fact that all the regions which are not to be etched are covered with the Si₃N₄ layer 29a, sufficient etching selectivity is ensured. The result is the structure shown in FIG. 10.

In FIG. 10, the dielectric layer 7 and the second metal electrode 8 have been etched back to a height slightly below the top edge of the insulation collar 14. In a subsequent step, the surface of the trench filling is sealed by an Si₃N₄ layer 32, which is produced, for example, by an HDP (High Density Plasma) process, and a subsequent etchback, and an SiO₂ filling 33.

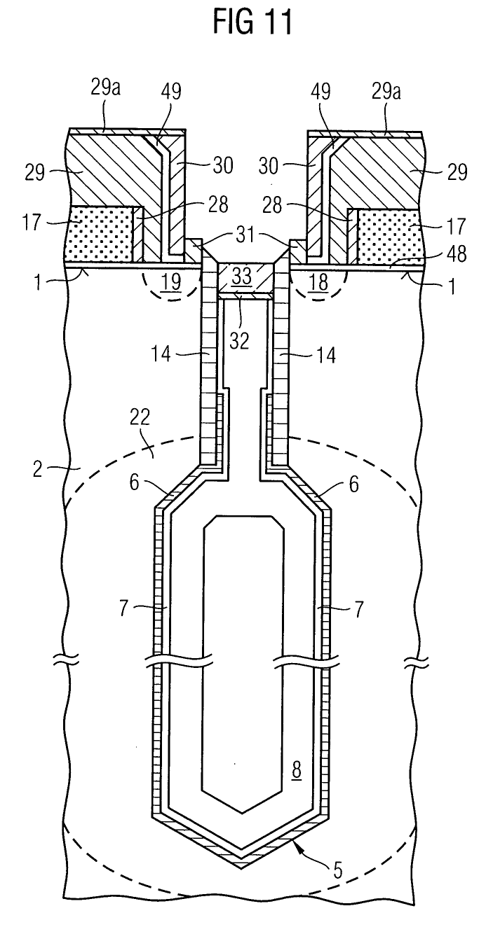

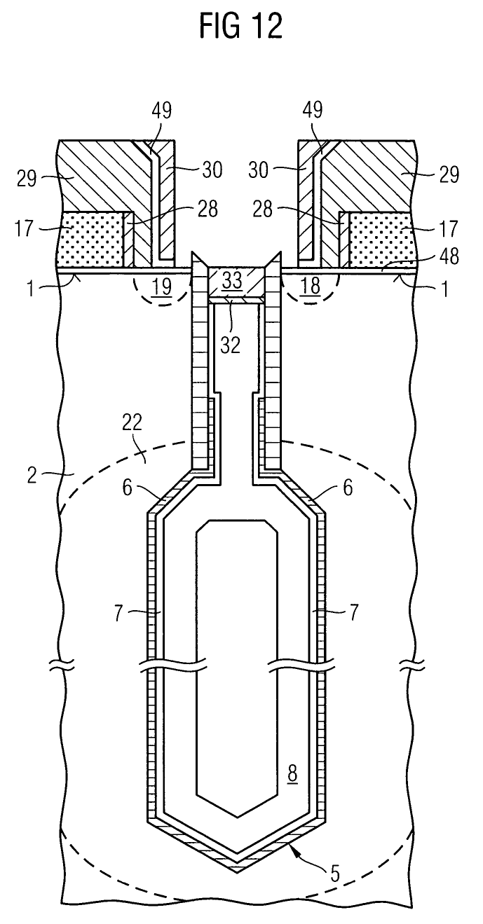

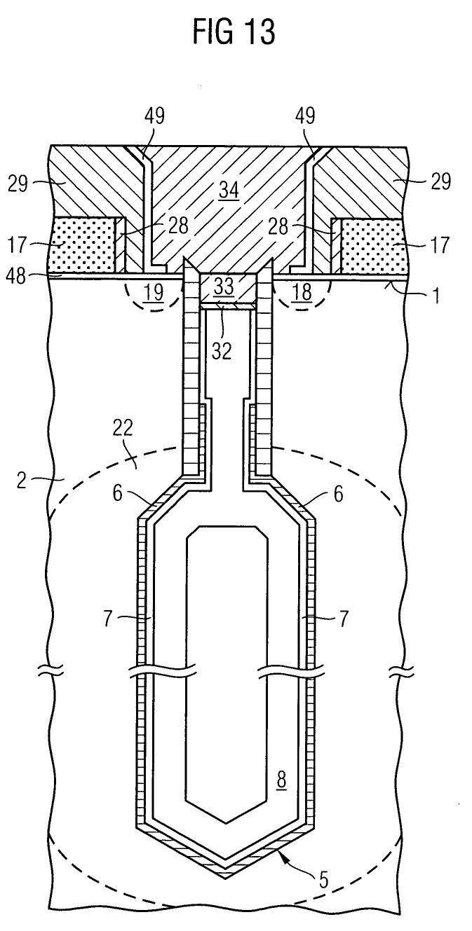

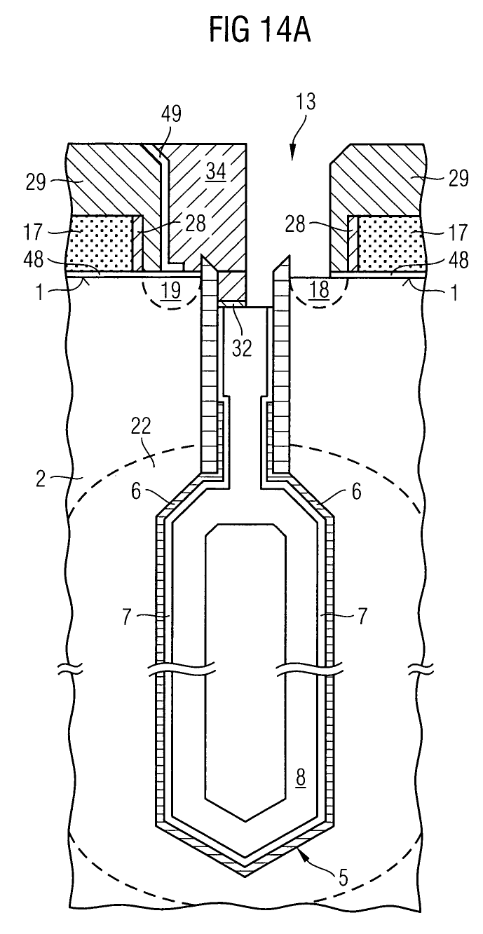

The result is the structure shown in FIG. 11. Then, an Si₃N₄ etching step is carried out, with the result that on the one hand the Si₃N₄ layer 29a and also the Si₃N₄ filling 31 which remains between the insulation collar 14 and the residues of the BPSG layer 30 are removed. The result is the structure shown in FIG. 12. Then, an SiO₂ layer 34 is deposited by a TEOS process, and a CMP (Chemical Mechanical Polishing) process is carried out on the surface of the Si₃N₄ layer 29. The result is the structure shown in FIG. 13.

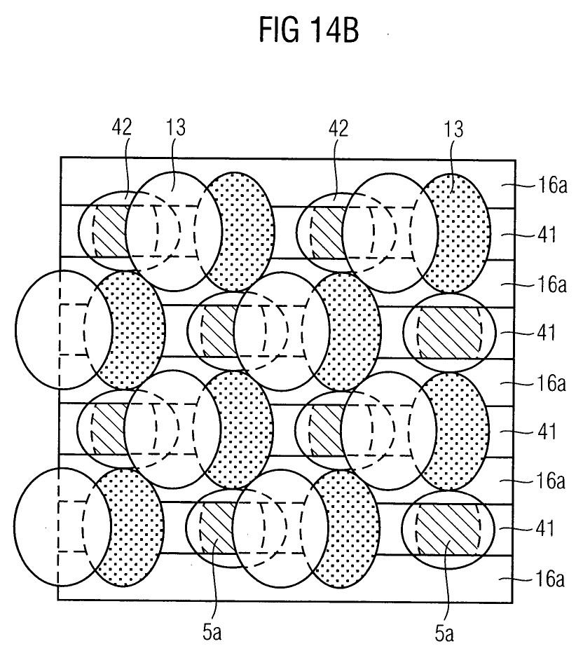

Then, after photolithographic patterning, the SiO₂ filling 34 is partially opened up to form a surface strap, in such a manner that the surface of the second capacitor electrode 8 is uncovered. FIG. 14A illustrates the resulting structure with the defined surface strap region 13.

FIG. 14B illustrates a plan view of the resulting arrangement of capacitor trenches. When seen in three dimensions, a defined surface strap region 13 is in each case provided between the defined trench regions 5a and the gate electrodes 17.

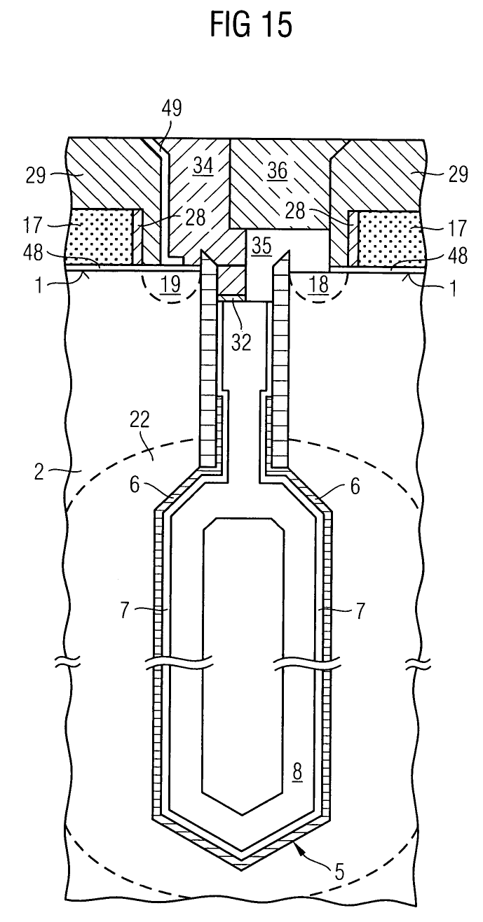

In a following step, first of all a surface strap material, for example a metal or polysilicon 35, is deposited in the defined surface strap region 13. The material which has been introduced is etched back, then a widening step is carried out, widening the previously defined strap surface region 13 in its upper part, and an Si₃N₄ layer 36 is deposited in the space which ensues. The result is the structure shown in FIG. 15.

In a subsequent step, the word lines are defined by a Damascene process. For this purpose, the regions through which the word lines will run are photolithographically defined and etched in the Si₃N₄ layers 29 and 36 by known methods. Then, a material for the word lines, for example tungsten, is deposited over the entire surface by known methods and planarized by a CMP process. As an alternative, it is, of course, also possible for a metal layer or a metal layer stack, for example of Al and W, to be applied over the entire surface and then patterned. Then, an Si₃N₄ layer 38 is applied as a spacer layer and capping layer.

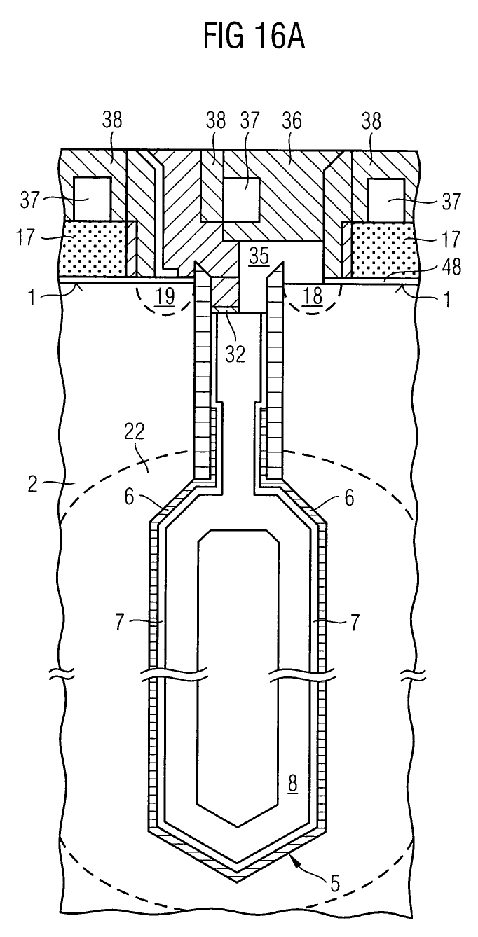

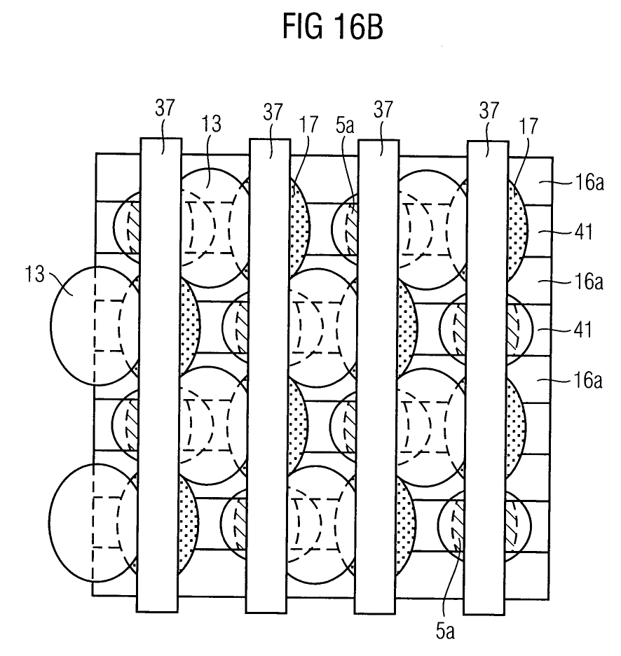

The result is the structure shown in FIG. 16A, in which reference numerals 37 denote the word lines which are in each case connected to the gate electrodes 17.

FIG. 16B shows a plan view of the resulting memory cell arrangement, in which the word lines 37 now run perpendicular to the active areas 41. The word lines 37 in each case connect the gate electrodes 17 of a column.

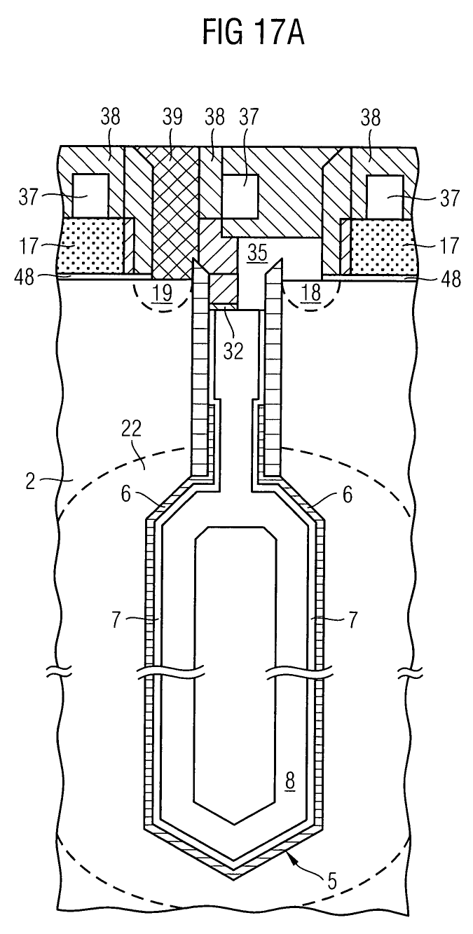

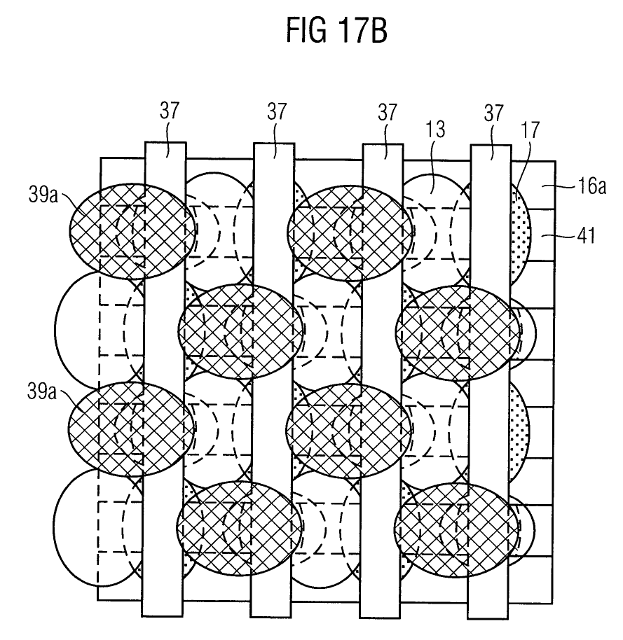

FIG. 17A shows the cross section through a memory cell according to the invention after a step for producing bit line contacts 39 has been carried out. For this purpose, first of all an opening for a bit line contact is photolithographically patterned into the surface which results after the step shown in FIG. 16A, and this opening is filled with a suitable metal or alternatively doped polysilicon. The structure shown in FIG. 17A results after a planarization step.

FIG. 17B shows a plan view of the resulting memory cell arrangement, in which in each case defined bit line contact openings 39a, which connect the second source/drain region 19 of each select transistor to the bit line that is subsequently to be formed, are provided above the active areas 41.

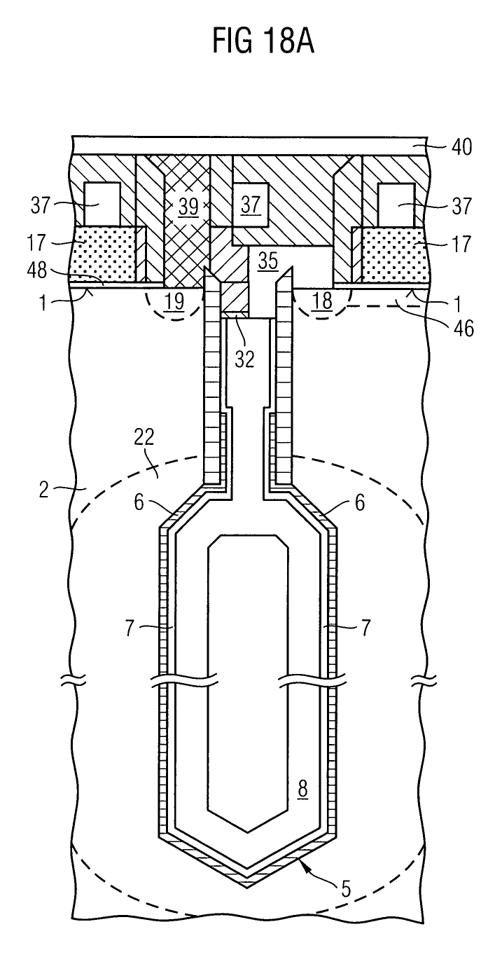

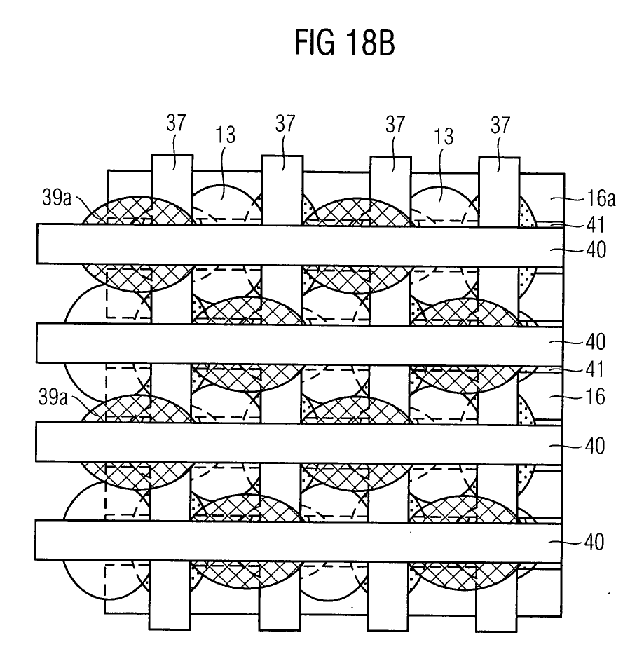

In a subsequent step, the MO metallization level is produced by first of all depositing a metal layer over the entire surface using known methods and patterning this metal layer by reactive ion etching to form bit lines 40. The resulting structure is shown in FIG. 18A.

When the memory cell illustrated is operating, the charge which is stored in the storage capacitor 10 is read via the surface strap region 35 and the first source/drain region when the select transistor is caused to respond. When the select transistor responds, via the word line 37, the gate electrode is placed at a suitable potential such that a conductive channel 46 is formed between the first and second source/drain regions. The charge which has been read is transmitted from the second source/drain region 19 via the bit line contact 39 to the associated bit line 40.

FIG. 18B shows a plan view of the resulting memory cell arrangement. As shown in FIG. 18B, the bit lines 40 are arranged in strip form in each case perpendicular to the word lines 37. The bit lines 40 are connected to the second source/drain regions 19 of the select transistors above the active areas 41 and parallel thereto via the bit line contacts 39a.

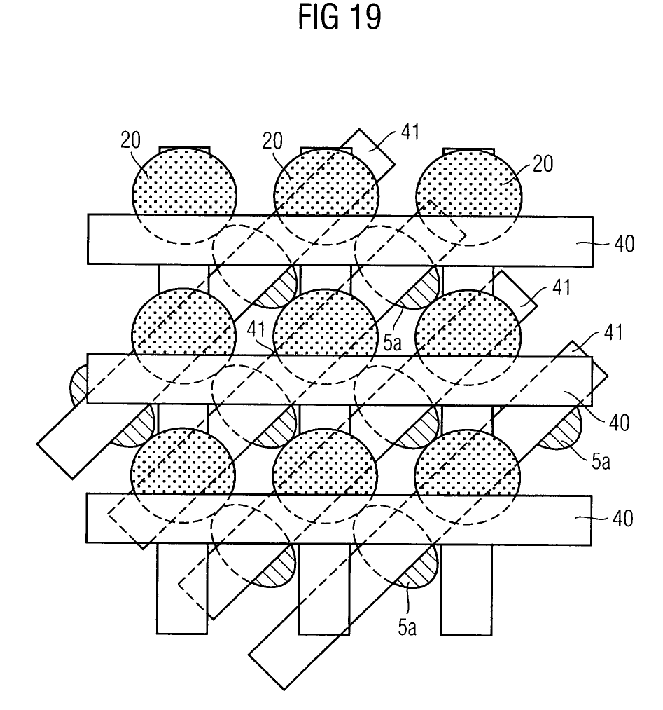

FIG. 19 shows a diagrammatic plan view of a further memory cell arrangement which can be fabricated with the method of the invention. In FIG. 19, the defined trench regions 5a are arranged in rows and columns in the form of a regular grid. The bit lines 40 run along the direction of the rows and the word lines 20 run perpendicular with respect thereto, i.e. in the direction of the columns. The defined active areas 41 in each case run parallel to one another in a direction which differs from the column or row direction. More specifically, the angle between the defined active areas 41 and the bit lines is preferably 45°. The word lines 20 are arranged in such a manner that they run precisely between two adjacent columns of defined trench regions.

Consequently, during the fabrication of the memory cell arrangement illustrated in FIG. 19, the trench regions 5a are not covered by word lines or gate electrodes, but rather they are freely accessible until the bit line 40 is formed. Accordingly, it is possible for the first capacitor electrode, the capacitor dielectric and the second capacitor electrode to be formed in the capacitor trenches even after the word line or gate electrodes have been completed. Furthermore, with a memory cell arrangement of this type, it is possible for the connection between first source/drain region 18 and the second capacitor electrode to be provided after completion of the trench capacitor by what is known as a surface strap. The bit lines 40 which run above the defined capacitor trenches are only produced after the capacitor trenches have been completed. They run in a plane above the word line plane.

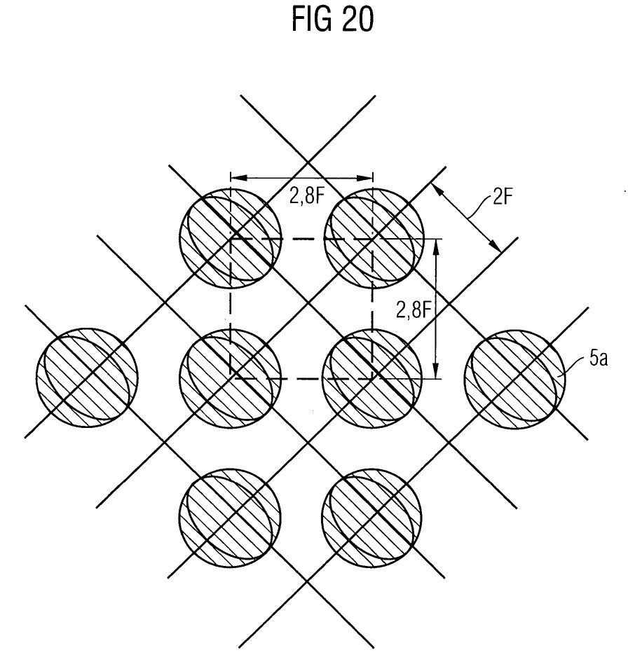

The method for fabricating the memory cell arrangement in accordance with the second exemplary embodiment of the present invention as illustrated in FIG. 19 is described with reference to FIGS. 20 to 26. Since the cross-sectional views following the individual process steps are in each case identical to those shown in FIGS. 1 to 18A, only the plan views which result after the respective process steps have been carried out are described.

In FIG. 20, a multiplicity of defined trench regions Sa are arranged in the form of a regular grid, i.e. the checkerboard arrangement of defined trench regions of the 8F² cell shown in FIG. 1B has been rotated through 45°. The distance between adjacent rows or columns is in each case 2.8 F, where F denotes the minimum feature size of the particular technology used. The cross section of the defined capacitor trenches is in each case elliptical or round.

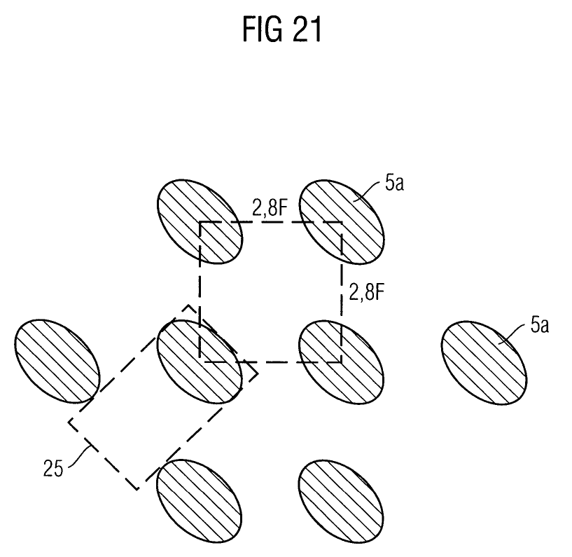

FIG. 21 shows a plan view of the arrangement of defined trench regions 5a after the method for fabricating the capacitor trenches shown in FIG. 1A has been carried out. In this case too, the capacitor trenches in their upper region may have epitaxially grown silicon regions 11, which are illustrated in FIG. 1C, in which raised source/drain regions are subsequently formed. In FIG. 21, reference numeral 25 denotes, by way of example, the section in which the memory cell is subsequently to be formed.

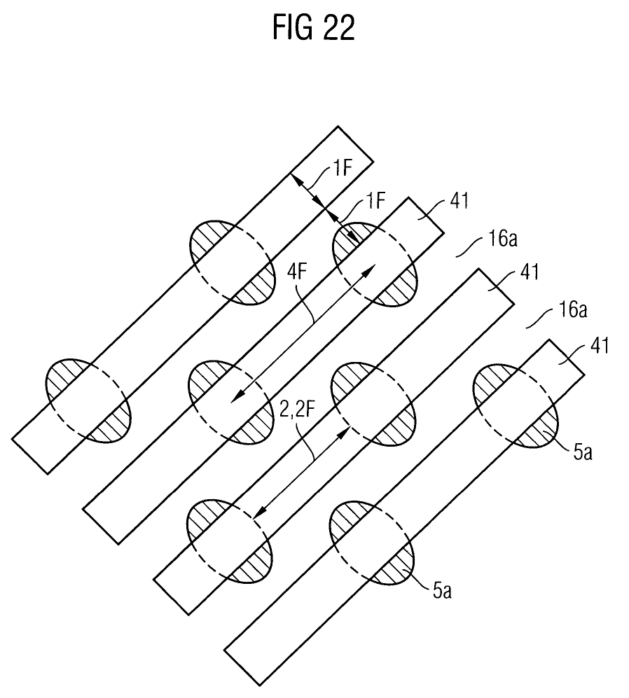

FIG. 22 illustrates the arrangement of the defined trench regions after the step described with reference to FIG. 2A for defining the active areas 16a has been carried out. The mask for defining the isolation trenches 16a is in this case rotated in such a manner that in the resulting arrangement the active areas do not run parallel to the direction of the rows or columns. More specifically, the active areas 41 have been rotated through the same angle by which the checkerboard-like arrangement of defined trench regions was previously also rotated.

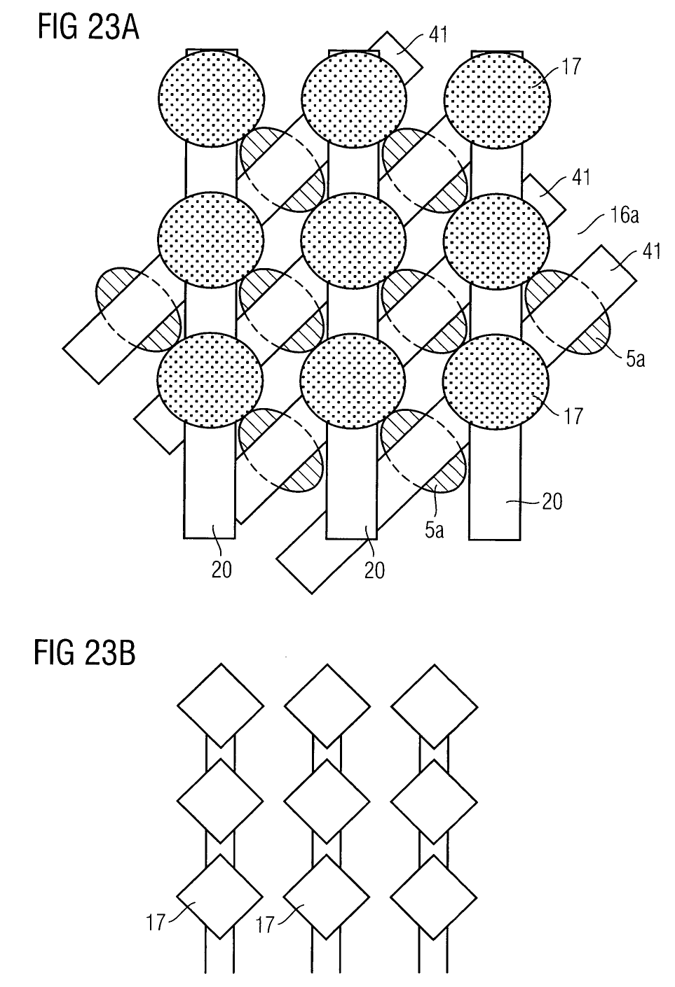

FIGS. 23A and 23B in each case illustrate a plan view of the arrangement of defined trench regions 5a after the gate electrodes 17 and the word lines 20 have been formed. In this case, word lines and gate electrodes can be formed in one step, but it is also possible for the gate electrodes 17 to be formed first of all and the word lines 20 to be formed thereafter. In particular, the word line 20 can also be formed at a later time, for example after the source/drain regions have been defined or after the storage capacitors have been filled with capacitor dielectric and second capacitor electrode. In both cases, i.e. with split fabrication steps or alternatively with simultaneous production of word line and gate electrodes, it is possible for the gate electrode regions 17 to be formed with a larger cross section than the word line sections 20. In particular, word line and gate electrode 17 may each take the forms illustrated in FIGS. 23A and 23B.

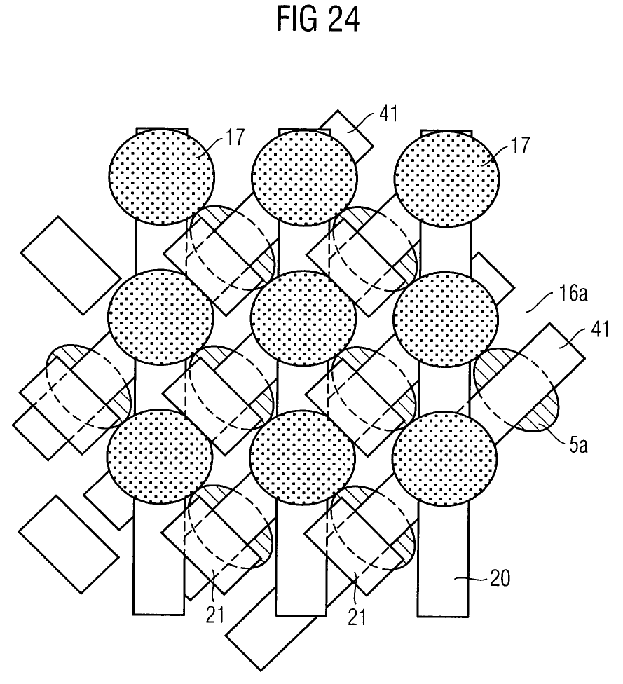

FIG. 23A shows a plan view after the method step described in FIG. 3A has been carried out, and FIG. 24 shows a plan view after the method step described in FIG. 5 has been carried out.

Then, the method steps for introducing the capacitor dielectric and the second capacitor electrode into the capacitor trench which have been described with reference to FIGS. 6 to 13 are carried out. During these steps, as in the exemplary embodiment described above, the first capacitor electrode can be formed before or after the gate electrode has been defined. Of course, to fabricate a memory cell arrangement as shown in FIG. 19, it is also possible first of all to complete the storage capacitor and then to form the gate electrode and the associated word lines.

FIG. 24 shows a plan view of the memory cell arrangement after the surface strap regions 21 have been defined. A cross section in which the steps for producing the surface strap are described has been described in FIGS. 13, 14A and 15. Since this layout includes a memory cell arrangement in which the word lines do not run above the defined capacitor trench regions 5a, it is possible to realize the connection between second capacitor electrode and first source/drain region 18 by a surface strap.

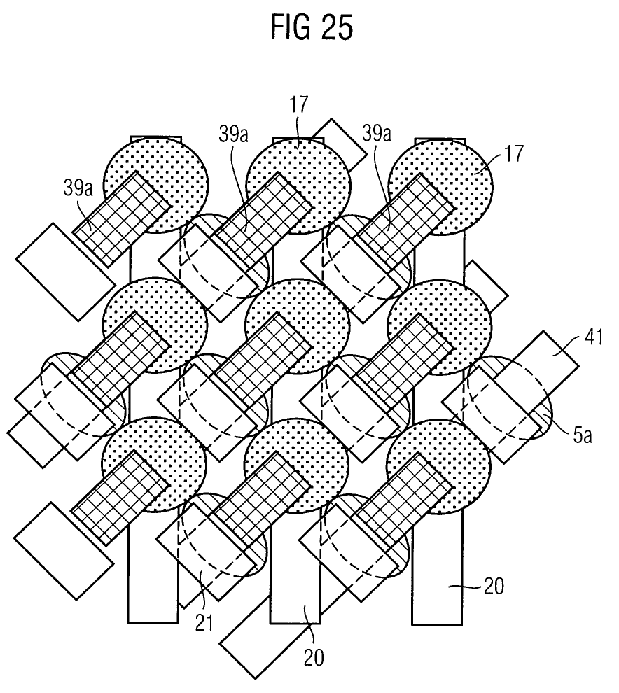

FIG. 25 shows a plan view of the memory cell arrangement after the bit line contact regions 39a have been defined. This corresponds to the method step which follows the process step shown in FIG. 17A.

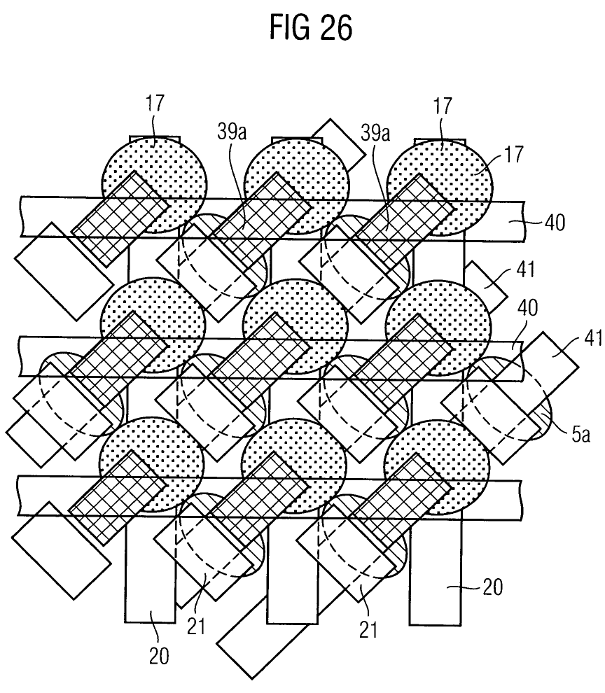

FIG. 26 illustrates a plan view of the memory cell arrangement after the bit line 40 has been produced, as described with reference to FIG. 18A.

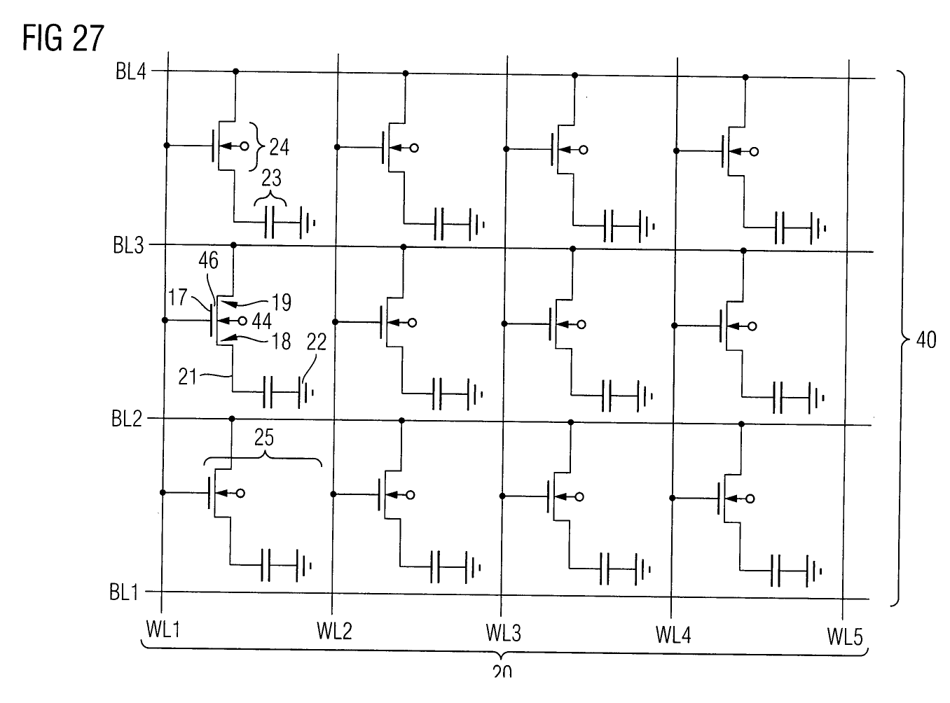

FIG. 27 shows a block circuit diagram of the memory cell arrangement illustrated in FIG. 26. In FIG. 27, a multiplicity of memory cells 25 are arranged in the form of a regular grid. Each memory cell 25 includes a storage capacitor 23 and a select transistor 24. The second capacitor electrode of the storage capacitor is connected to the first source/drain region 18 of the select transistor via a terminal 21. The gate electrode 17 is driven by a word line 20 and switches the conductive channel 46 between first and second source/drain regions 18, 19 to the on state when it is driven. A bit line 40 is in each case connected to the second source/drain region 19. The charge stored in the storage capacitor 23 is read via the bit line 40 when the gate electrode 17 is driven by a word line 20. To prevent the semiconductor substrate from being charged during the operations of switching the transistor on and off, a substrate discharge 44, which is usually realized by a suitably doped substrate region, is also provided.

In memory cell arrangements that include a folded bit line architecture, there are two word lines for each bit line, and consequently only every second node is connected. More specifically, each second word line is a passive word line, and only each second cell field is occupied by a memory cell. When a word line is driven, therefore, with the folded bit line architecture, in addition to the bit line that is to be read, the adjacent bit line is also read in parallel and the signals are compared in a read amplifier.

In the case of the memory cell arrangement illustrated in FIG. 27, if the word line WL1 is activated, both the memory cell located at the intersection point of WL1 and BL2 and the memory cell located at the intersection point between WL1 and BL3 would be activated. For this reason, a reference signal cannot be generated by tapping off the signal at the bit line BL3. The problem can be solved by introducing a second bit line level, in which there is a reference bit line for each bit line BL1, . . . , BL4 of the first bit line level.

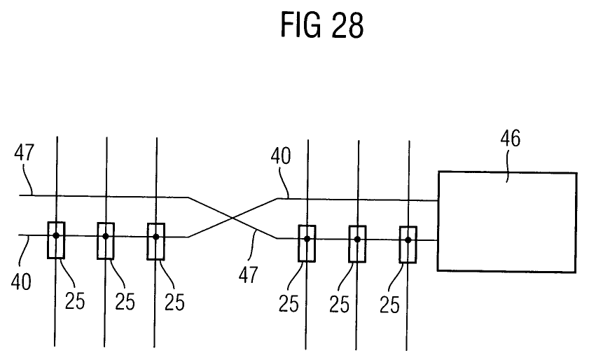

This is illustrated in FIG. 28. With the cell architecture shown in FIG. 28, in which, by way of example, a reference bit line 47 is provided in a higher metallization level and crosses the first bit line 40, so that the same number of memory cells 25 are connected to each of the two bit lines 40, 47, the signal from the bit line 40 can be compared with the signal from the reference bit line 47 in the read amplifier 46 when a specific memory cell responds.

This cell architecture is known as a vertically twisted bit line architecture. Since a second bit line level must be introduced, the process becomes somewhat more complex and expensive, but the omission of the passive word lines does give rise to a large number of benefits, in particular that, for example, the second capacitor electrode can be connected to the first source/drain region of the select transistor via a surface strap. A surface strap of this type is on the one hand particularly simple to realize, for example from a highly conductive material, and on the other hand it is also possible to avoid undesirable interactions between the strap region and gate electrode.

A further advantage results from the fact that, by virtue of the active area being rotated through 45°, the channel length can be increased to, for example, 1.5 F while the memory cell continues to take up the same amount of space, with the result that the characteristic variable I_{ON} is improved. The active areas are segmented and are in each case isolated from one another by capacitor trenches, so that it is possible to effectively avoid short circuits. Conversely, with this design, the distance between adjacent bit lines is increased to 2.8 F, with the result that the capacitive coupling between adjacent bit lines can be better suppressed.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

List of Designations

1 Surface
2 Semiconductor substrate
3 SiO₂ layer
4 Si₃N₄ layer
5 Trench
5a Defined trench region
6 First capacitor electrode
7 Capacitor dielectric
8 Second capacitor electrode
9 Intrinsic polysilicon filling
10 Si₃N₄ layer
11 Epitaxially grown silicon layer
12 Si₃N₄ layer
13 Defined surface strap region
14 Isolation trench
15 n⁺-doped polysilicon filling
16 SiO₂ insulation structure
16a defined isolation trench region
17 Gate electrode
17a Defined gate electrode region
18 First source/drain region
19 Second source/drain region
20 Word line
21 Surface strap
22 n⁺-doped region (buried plate)
23 Storage capacitor
24 Select transistor
25 Memory cell
26 Si₃N₄ layer
27 Si₃N₄ layer
28 SiO₂ spacer
29 Si₃N₄ layer
29a Si₃N₄ layer
30 SiO₂ layer
31 Si₃N₄ filling
32 Si₃N₄ layer
33 SiO₂ filling
34 SiO₂ filling
35 Metal filling
36 Si₃N₄ filling
37 Gate conduction strip
38 Si₃N₄ layer
39 Bit line contact metal
39a Defined bit line contact region
40 Bit line
41 Defined active area
42 Mask opening of the DTII mask
43 Read amplifier
44 Substrate terminal
45 Bit line of the second bit line level
46 Conductive channel
47 Trench wall
48 Gate oxide layer
49 Si₃N₄ liner

What is claimed:

1. A method for fabricating a memory cell that is at least partially arranged in a semiconductor substrate and includes a storage capacitor configured as a trench capacitor that is suitable for storing electrical charge and a select transistor that is suitable for driving the storage capacitor, the method comprising:
providing a semiconductor substrate;
etching a trench into a surface of the semiconductor substrate and producing a trench wall;
providing a select transistor including a first source/drain region and a second source/drain region, a conductive channel in the semiconductor substrate that extends between the first and second source/drain regions, and a gate electrode;
forming a storage capacitor including a first capacitor electrode that is adjacent the trench wall, a dielectric layer that is adjacent the capacitor electrode, and a second capacitor electrode that is adjacent the dielectric layer; and
electrically connecting the second capacitor electrode to the first source/drain region of the select transistor;
wherein the capacitor trench is initially filled with dummy material that is removed after forming the first and second source/drain regions and the gate electrode, and the dielectric layer and the second capacitor electrode of the storage capacitor are formed after the first and second source/drain regions of the select transistor are provided.

2. The method of claim 1, wherein forming the first capacitor electrode comprises doping a substrate region that is adjacent the trench wall.

3. The method of claim 1, wherein forming the first capacitor comprises depositing a metal layer.

4. The method of claim 1, wherein the first capacitor electrode is formed after the first and second source/drain regions are provided and before the dielectric layer is formed.

5. The method of claim 4, wherein the dummy material is deposited in the trench before the gate electrode is provided, and the dummy material is removed prior to forming the first capacitor electrode.

6. The method of claim 1, wherein the first capacitor electrode (6) is formed after the trench is etched and before the gate electrode is provided.

7. The method of claim 1, wherein the dummy material is deposited in the trench after the first capacitor electrode is formed and before the gate electrode is provided, and the dummy material is removed before the dielectric layer is formed.

8. The method of claim 1, wherein the dummy material comprises silicon or silicon-germanium.

9. The method of claim 1, wherein the first and second source/drain regions are provided after the gate electrode is formed.

10. The method of claim 1, wherein the second capacitor electrode is electrically connected to the first source/drain region of the select transistor after the second capacitor electrode is formed.

11. A method of fabricating a memory cell arrangement including a plurality of memory cells, a plurality of word lines arranged in a first direction and a plurality of bit lines arranged in a second direction intersecting the first direction all formed at least partially in a semiconductor substrate, each memory cell comprising a storage capacitor to store electrical charge and a select transistor to drive the storage capacitor, the method comprising:
forming a plurality of memory cells, each memory cell formed according to the method of claim 1;
providing a plurality of word lines formed from an electrically conductive material, wherein each word line is connected to a plurality of gate electrodes, with each gate electrode being assigned to memory cells arranged in the first direction, so as to drive the gate electrodes to trigger a read operation;
providing a plurality of bit lines formed from an electrically conductive material to facilitate the transmission by the bit lines of an electrical charge that has been read; and
providing bit line contacts that are arranged such that the second source/drain region of a select transistor is connected to a respective bit line;
wherein, for each memory cell, at least one gate electrode is initially fabricated to be insulated from all other gate electrodes that are assigned to a respective word line, and the at least one gate electrode is only connected to all other gate electrodes assigned to the respective word line via the respective word line assigned to the corresponding word line in a subsequent process step.

12. A method for fabricating a memory cell arrangement, including a multiplicity of memory cells formed at least partially in a semiconductor substrate, each memory cell comprising a storage capacitor to store electrical charge and a select transistor to drive the storage capacitor, a multiplicity of word lines arranged in a first direction, and a plurality of bit lines arranged in a second direction intersecting the first direction, the method comprising:
forming a plurality of memory cells, each memory cell formed according to the method of claim 1;
providing a plurality of word lines formed from an electrically conductive material, wherein each word line is connected to a plurality of gate electrodes, with each gate electrode being assigned to memory cells arranged in the first direction, so as to drive the gate electrodes to trigger a read operation;
providing a plurality of bit lines formed from an electrically conductive material to facilitate the transmission by the bit lines of an electrical charge that has been read; and
providing bit line contacts that are arranged such that the second source/drain region of a select transistor is connected to a respective bit line;
wherein the direction of the conductive channel that extends between the first and second source/drain regions of the select transistor of each memory cell differs from the directions of the bit lines and of the word lines.

13. The method of claim 12, wherein each conductive channel extends in a direction that differs by 45° from the direction of the bit lines.

14. The method of claim 12, wherein, for each memory cell, at least one gate electrode is initially fabricated to be insulated from all other gate electrodes that are assigned to a respective word line, and the at least one gate electrode is only connected to all other gate electrodes assigned to the respective word line via the respective word line assigned to the corresponding word line in a subsequent process step.

15. A memory cell arrangement comprising:
a plurality of memory cells at least partially formed in a semiconductor substrate, each memory cell comprising a storage capacitor to store electrical charge and a select transistor to drive the storage capacitor;
a plurality of word lines arranged in a first direction;
a plurality of bit lines arranged in a second direction intersecting the first direction;
wherein:
the storage capacitor of each memory cell comprises at least a first capacitor electrode, a storage dielectric, and a second capacitor electrode;
the select transistor comprises at least one gate electrode formed from an electrically conductive gate material, a first source/drain region and a second source/drain region, the second capacitor electrode of the storage capacitor is connected to the first source/drain region of the select transistor, the first and second source/drain regions are connected to one another via a conductive channel region arranged in the semiconductor substrate, and the at least one gate electrode is adjacent to and electrically insulated from the channel region;
each word line is connected to a plurality of gate electrodes assigned to memory cells arranged in the first direction so as to drive the gate electrodes connected to the word line to trigger a read operation;
the second source/drain region of the select transistor of each memory cell is connected via a bit line contact to a respective bit line that is configured to transmit an electrical charge that has been read; and
the direction of each conductive channel, which extends between respective first and second source/drain regions, differs from the direction of the bit lines and the word lines, and lower edges of the gate electrodes, when viewed in cross-section along each conductive channel region, are disposed at different distances from the substrate surface than lower edges of the word lines.

16. The memory cell arrangement of claim 15, wherein each conductive channel extends in a direction that differs by 45° from the direction of the bit lines.
